(19) United States
(12) Patent Application Publication
(10) Pub. No.: US 2012/0082800 A1
(43) Pub. Date: Apr. 5, 2012

(54) METHOD FOR MANUFACTURING MAGNETIC RECORDING MEDIUM

(75) Inventors: Masatoshi SAKURAI, Tokyo (JP); Kaori Kimura, Yokohama-shi (JP); Yoshiyuki Kamata, Tokyo (JP); Takeshi Iwasaki, Tokyo (JP)

(73) Assignee: Kabushiki Kaisha Toshiba, Tokyo (JP)

(21) Appl. No.: 13/216,555

(22) Filed: Aug. 24, 2011

(30) Foreign Application Priority Data
Sep. 30, 2010 (JP) P2010-223216

(51) Int. Cl. C23C 14/04

(52) U.S. Cl. 427/526

(57) ABSTRACT

According to one embodiment, there is provided a method for manufacturing a magnetic recording medium, the method including: depositing a magnetic recording layer on a substrate; forming a mask on a region of the magnetic recording layer corresponding to a recording area; irradiating another region of the magnetic recording layer where the mask is not formed with an ion beam using a C-containing gas as a source gas to deactivate the another region and to thereby form a non-recording area; and forming a protective film over an entire surface of the substrate.

### CROSS-REFERENCE TO RELATED APPLICATION(S)

This application is based upon and claims the benefit of priority from Japanese Patent Application No. 2010-223216, filed on Sep. 30, 2011, the entire contents of which are incorporated herein by reference.

### FIELD

Embodiments described herein relate generally to a method for manufacturing a magnetic recording medium.

### BACKGROUND

Recently, in a magnetic recording medium incorporated into a hard disk drive (HDD), enhancement of the track density is inhibited due to interference between adjacent tracks. To enhance the track density, it is important to reduce a writing blur attributable to a fringe effect of a recording head magnetic field.

In view of above, a discrete track-type patterned medium (DTR medium) in which recording tracks are physically separated, and a bit patterned medium (BPM) in which recording bits are physically separated, have been proposed. Such patterned medium can have an increased track density because a side erase during recording and a side read during reproduction can be reduced, and these mediums are promising as a high-density magnetic recording medium. In this specification, the term “patterned medium” includes the DTR medium and the BPM.

When recording or reproducing a medium (patterned medium) having surface convexes/concaves by a flying head, the flying property is important. For example, in a DTR medium, with an attempt to completely separate adjacent tracks, a groove is formed to a total depth of 20 nm by removing a magnetic recording layer composed of a ferromagnetic material of about 15 nm in thickness and a protective layer of about 5 nm in thickness. On the other hand, the designed flying amount of the flying head is about 10 nm. Therefore, ensuring of the flying property of the head by filling the groove with a nonmagnetic material and thereby smoothing the DTR medium surface has been considered. However, such smoothing process is difficult.

Instead, a method of patterning a smooth magnetic recording layer by local transformation has been proposed (JP-2009-087454-A and JP-2008-077756-A).

However, in JP-2009-087454-A and JP-2008-077756-A, the non-recording area for dividing the recording area of the patterned medium is magnetically separated from the recording area by completely omitting a magnetic material or depriving the non-recording area of magnetism through fluorination or reduction in the Co concentration. In the deactivation by fluorination or the like, when the recording layer contains easily volatile elements including fluorine, a free atom incapable of being completely bonded volatilizes to bring about a phenomenon of the deactivation effect being weakened or transfers to the recording layer to cause a problem of corrosion, failing in allowing the finished medium to have sufficiently high environmental resistance.

### BRIEF DESCRIPTION OF DRAWINGS

A general architecture that implements the various feature of the present invention will now be described with reference to the drawings. The drawings and the associated descriptions are provided to illustrate embodiments and not to limit the scope of the present invention.

FIG. 1 is a cross-sectional view of the magnetic recording medium in an embodiment.

FIG. 2 is a plan view of the discrete track medium in an embodiment.

FIG. 3 is a plan view of the patterned medium in an embodiment.

FIGS. 4A to 4J are cross-sectional views showing the method for manufacturing a patterned medium according to an embodiment.

FIGS. 5A to 5G are cross-sectional views showing the method for manufacturing a patterned medium according to another embodiment.

FIGS. 6A to 6K are cross-sectional views showing the method for manufacturing a patterned medium according to still another embodiment.

### DETAILED DESCRIPTION

In general, according to one embodiment, there is provided a method for manufacturing a magnetic recording medium, the method including: depositing a magnetic recording layer on a substrate; forming a mask on a region of the magnetic recording layer corresponding to a recording area; irradiating another region of the magnetic recording layer where the mask is not formed with an ion beam using a C-containing gas as a source gas to deactivate the another region and to thereby form a non-recording area; and forming a protective film over an entire surface of the substrate.

An embodiment will be described below by referring to the drawings.

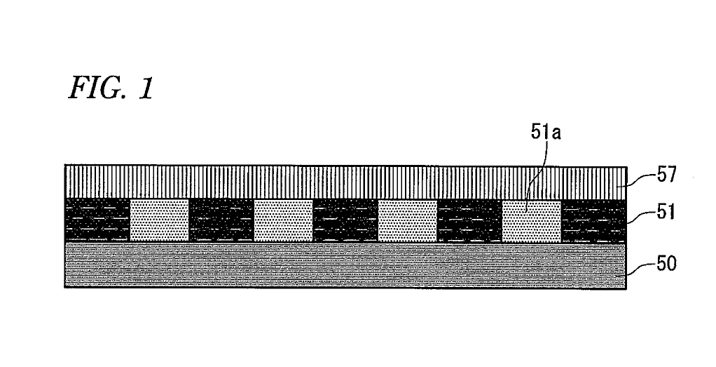

FIG. 1 shows a cross-sectional view of the patterned medium of the magnetic recording medium in an embodiment.

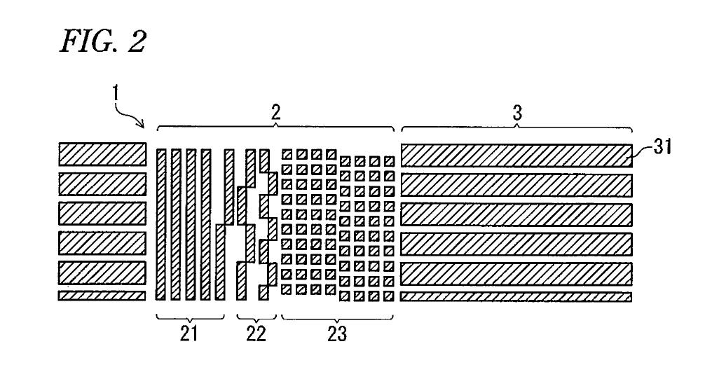

FIG. 2 shows a plan view along the circumferential direction of a discrete track medium (DTR medium) that is one example of the patterned medium manufactured using the method in an embodiment. As shown in FIG. 2, a servo region 2 and a data region 3 are alternately formed along the circumferential direction of a patterned medium 1. The servo region 2 contains a preamble part 21, an address part 22 and a burst part 23. The data region 3 contains a discrete track 31 in which adjacent tracks are separated from each other.

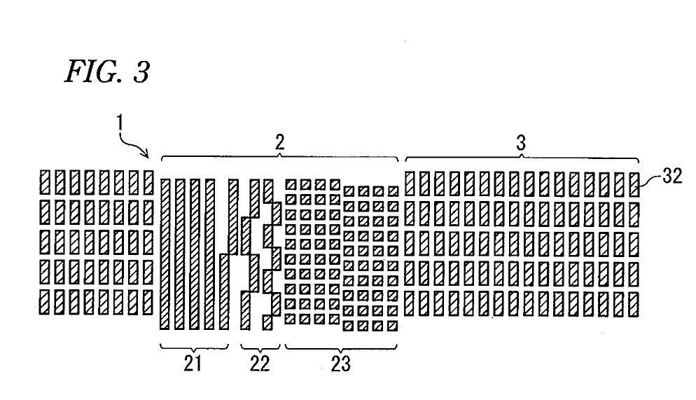

FIG. 3 shows a plan view along the circumferential direction of a bit pattern that is another example of the patterned medium manufactured using the method in an embodiment. In this patterned medium, magnetic dots 32 are formed in the data region 3.

### Example 1

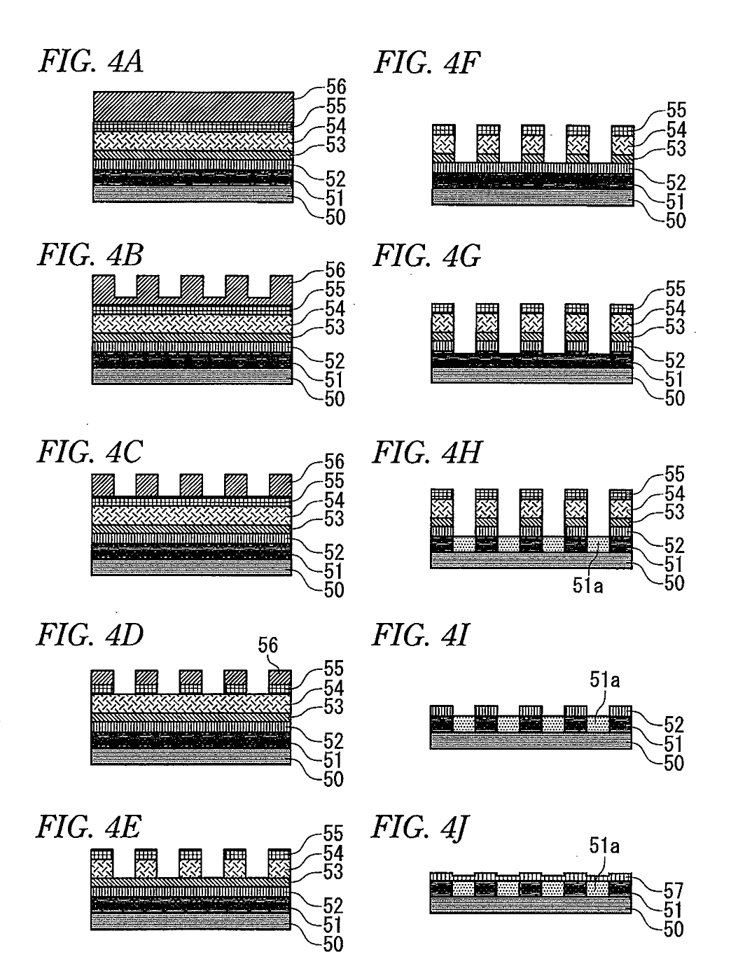

One example of the method for manufacturing a magnetic recording medium according to an embodiment is described by referring to FIGS. 4A to 4J.

As shown in FIG. 4A, a 40 nm-thick soft magnetic layer (CoZrNb) (not shown), a 20 nm-tick orientation controlling underlying layer (Ru) (not shown), a 20 nm-thick magnetic recording layer 51 (CoCrPt—SiO₂) and a 5 nm-thick DLC protective layer 52 are deposited on a glass substrate 50. A 5 nm-thick first hard mask 53 composed of Mo, a 25 nm-thick second hard mask 54 composed of carbon, and a 3 nm-thick third hard mask 55 composed of Si are deposited thereon. On the third hard mask 55, a resist 56 is spin-coated to have a thickness of 50 nm.

Separately, a stamper 60 having a concave/convex pattern (for example, as shown in FIG. 2 or 3) formed thereon is prepared. The stamper 60 is produced through EB lithography, Ni electroforming and injection molding. The stamper 60 is disposed by arranging its concave/convex surface to face the resist 56.

As shown in FIG. 4B, the stamper 60 is imprinted on the resist 56 to transfer the concave/convex pattern of the stamper 60 to the resist 56. Thereafter, the stamper 60 is removed. A resist residue is remaining in the bottom of the concave of the concave/convex pattern transferred to the resist 56.

As shown in FIG. 4C, the resist residue in the concave is removed by dry etching to expose the surface of the third hard mask 55. This process is performed, for example, in an inductively coupled plasma (ICP) RIE apparatus by using CF₄ as the process gas and setting the chamber pressure to 0.1 Pa, the coil RF power and the platen RF power to 100 W and 50 W, respectively, and the etching time to 60 seconds.

As shown in FIG. 4D, the pattern is transferred to the third hard mask 55 by ion beam etching while using the patterned resist 56 as the mask, to expose the second hard mask 54 in concave parts. This process is performed, for example, in an inductively coupled plasma (ICP) RIE apparatus by using CF₄ as the process gas and setting the chamber pressure to 0.1 Pa, the coil RF power and the platen RF power to 100 W and 50 W, respectively, and the etching time to 20 seconds.

As shown in FIG. 4E, the pattern is transferred by etching the second hard mask 54 composed of C while using the patterned third hard mask 55 as the mask, to expose the surface of the first hard mask 53 in concave parts. This process is performed, for example, in an inductively coupled plasma (ICP) RIE apparatus by using O₂ as the process gas and setting the chamber pressure to 0.1 Pa, the coil RF power and platen RF power to 100 W and 50 W, respectively, and the etching time to 20 seconds.

As shown in FIG. 4F, the pattern is transferred by etching the first hard mask 53 composed of Mo while using the patterned second hard mask 54 as the mask, to expose the surface of DLC 52 in concave parts. This process is performed, for example, in an ion milling apparatus by using an Ar gas and setting the chamber pressure to 0.06 Pa, the accelerating voltage to 400 V, and the etching time to 10 seconds.

As shown in FIG. 4G, the pattern is transferred by etching DLC 52 while using the patterned first hard mask 53 as the mask, to expose the surface of the magnetic recording layer 51 in concave parts. This process is performed, for example, in an inductively coupled plasma (ICP) RIE apparatus by using O₂ as the process gas and setting the chamber pressure to 0.1 Pa, the coil RF power and the platen RF power to 100 W and 50 W, respectively, and the etching time to 5 seconds.

As shown in FIG. 4H, implantation of C element into the magnetic recording layer 51 is performed to form a C-containing layer 51a. This process is performed, for example, with an ECR (electron cyclotron resonance) ion gun by using a CH₄ gas at a gas pressure of 0.04 Pa with a microwave power of 1,000 W and an accelerating voltage of 5,000 V for a processing time of 60 seconds.

As shown in FIG. 4I, the remaining first hard mask (Mo) 53 with the layer thereon is removed. In this process, for example, the medium is dipped in aqueous hydrogen peroxide and held for 1 minute to remove all of the remaining second hard mask 54 and the film deposited thereon.

As shown in FIG. 4J, a protective film 57 is formed by CVD (chemical vapor deposition) and a lubricant is coated thereon, whereby a patterned medium (DTR medium, BPM, etc.) according to an embodiment is obtained.

The characteristic features of this embodiment are described in detail below.

<Medium Having C-Containing Non-Recording Area>

The magnetic recording layer in this embodiment consists of a recording area mainly composed of a magnetic element, and a non-recording area formed by adding a C element to the recording area. In the non-recording area, the addition of C enables deactivating the magnetism and enhancing the fringe performance of the medium. Furthermore, the medium in which C is added has resistance to heat or humidity and exhibits good environmental resistance. The elements constituting the non-recording area contain at least the same element as that in the recording area. By containing the same element, unevenness of the composition can be reduced and the resistance to corrosion can be improved.

The C concentration is preferably 1% or more of the magnetic element in terms of the atomic ratio. When 1% or more of this element is contained, the lattice of the recording layer can be distorted to deactivate the magnetism. Whether 1% or more of the element is contained can be easily measured by an analysis method such as EDX and EELS. Also, when 20% or more of the element is contained, the Ms can be reduced to 20% or less, and this is more preferred in view of fringe characteristics of the medium.

Addition of C is not achieved only by depositing it on the magnetic recording layer by CVD, sputtering or the like method. For example, even when DLC is deposited as a protective film on the magnetic recording layer, C does not diffuse into the recording layer in a concentration of 1% or more. Also, even when the portion corresponding to the non-recording area is etched to half the thickness and concave/convex implanting with C is performed, the characteristics of the present invention are not obtained.

It is preferred to aggressively add C by the following method.

Although both of the non-recording area (C-containing layer 51a) and the DLC protective layer 52 contain C, it is possible to distinguish them from each other, because only the non-recording area contains an element which is used in the magnetic recording layer 51. For example, a boundary between the non-recording area (C-containing layer 51a) and the DLC protective layer 52 may be determined by performing the point analysis with the cross-sectional TEM-EELS to analyze the spectrum.

<Patterning of Magnetic Recording Layer>

The step for patterning the magnetic recording layer, included in the manufacturing method of this embodiment, can be performed by irradiating with an ion beam and thereby deactivating the magnetic recording layer. By deactivation of the magnetism, the fringe characteristics of the magnetic recording medium are enhanced. By implanting a C element in the non-recording area of the magnetic recording layer, particularly the mechanical strength of the recording layer can be increased.

The magnetism deactivation step in this embodiment indicates a step of weakening the magnetism in the area exposed by the mask of the magnetic recording layer, compared with the magnetism in the area covered with the mask. Weakening of the magnetism means to effect soft magnetization, non-magnetization or diamagnetization. Such a change in the magnetism can be observed by measuring Ms, Hn, Hs, Hc or the like value by means of VSM (vibrating sample magnetometer) or a Kerr (magneto-optical Kerr effect) measuring apparatus.

In the method of this embodiment, the magnetism deactivation step can be performed by irradiating with an ion beam. Upon ion beam irradiation, a C element is caught between lattices of elements constituting the magnetic recording medium or caused to substitute for the recording layer element, whereby the magnetism can be weakened. The ion beam irradiation is performed is irradiated at an accelerating energy of approximately from 500 eV to 20 keV by plasma conversion using an ECR (electron cyclotron resonance) system or an RF power source. By this irradiation, the magnetic recording layer can be implanted with a C element and deprived of the magnetism.

When performing the deactivation by directly irradiating the magnetic recording layer with an ion beam, CO, CO₂, CH₄, C₂H₂, C₂H₄, C₂H₆, C₃H₆, C₃H₈, C₄H₆, C₄H₈, C₄H₁₀, HCN or CH₃F is preferably used as the ion beam source.

By using such a gas, a C element can be efficiently implanted into the exposed magnetic recording layer. A gas species having a large molecular weight brings about etching of the magnetic recording layer and its use is not preferred. It is also disadvantageous to contain many corrosive elements such as fluorine and chlorine, because a problem of corrosion is caused due to their reaction with an element constituting the recording layer.

At the time of implanting a C element, it is effective to mix an assist gas such as He, Ne, Ar, Kr, Xe, H₂, N₂, O₂ and O₃. By mixing such a gas, the magnetic recording layer can be amorphized and the deactivation effect can be more increased. To obtain the C implanting effect, the partial pressure ratio of the assist gas may be set to 75% or less.

Deactivation may also be performed by depositing a C-containing layer on the magnetic recording layer and irradiating with an ion beam. In this case, in order to obtain a sufficiently high C implanting effect, the layer deposited is preferably composed to have a C concentration of 50% or more in terms of atomic ratio. As for the layer deposited, the effect is obtained as long as 50% of C is contained, but when any one of C, CN, AlC, SiC, TiC, VC, CrC, ZrC, NbC, MoC, TaC and WC or a mixture thereof is used, the effect is high, and above all, C, CN, CrC and VC are more preferred.

The film thickness of the deposited layer is preferably 30 nm or less and preferably 3 nm or more. If the film thickness is too large, C is excessively implanted and the C element diffuses even into the recording area, whereas if the thickness is too small, the total amount of C implanted is deficient.

After depositing the C layer, ion beam irradiation is performed to deactivate the magnetic layer in the non-recording area. The ion beam is preferably formed by generating plasma from a gas composed of He, Ne, Ar, Kr, Xe or a mixture thereof.

Gases such as N2 and O₂ react with and gasify C and therefore, are not preferred. The ion beam irradiation is continued until the C-containing layer is convexed or concaved to a depth of about 5 nm or less and depending on the case, even the magnetic recording layer is convexed or concaved.

In the case where etching occurs in the magnetic recording layer by the ion beam irradiation, in view of head flying, the concave/convex height of the magnetic recording layer is preferably 15 nm or less, more preferably 10 nm or less.

<Hard Mask>

The hard mask for use in the method of this embodiment preferably contains carbon as a main component. The atomic ratio of carbon preferably exceeds 75%. If the ratio of carbon is 75% or less, the etching selectivity tends to decrease, failing in processing the magnetic layer with good profile.

The hard mask can be deposited by sputtering or CVD. Also, other than carbon, Al, Si, Ta or Ti can be used as the hard mask. The film thickness of the hard mask is preferably from 4 to 50 nm. If the film thickness is too large, etching takes a long time when separating the hard mask and this gives rise to a damage in the side of the patterned film, whereas if it is excessively small, the film cannot fulfill the function as a hard mask during etching.

The hard mask functions also as a protective film of the raw material medium before processing and therefore, an oxide film between the magnetic recording layer and the hard mask may be omitted. Furthermore, a wet release layer may be deposited between the hard mask and the magnetic recording layer, if desired.

<Sub-Mask Between Hard Mask and Resist Layer>

For the sub-hard mask in the method of this embodiment, a material ensuring etching selectivity with respect to the hard mask is used and is preferably Si, SiO₂, SixNy, SiON, Al, Ta, Ti or a material mainly composed of Ag, Au, Co, Cr, Cu, Ni, Pd, Pt or Ru, which are resistant to an O₂ or O₃ gas. Also, an elemental substance, nitride, oxide, alloy or mixture thereof may be used.

The film thickness of the sub-hard mask is preferably from 1 to 15 nm, more preferably from 2 to 5 nm. If the film thickness is too large, the magnetic recording layer may be damaged when removing the sub-hard mask, whereas if it is excessively small, the mask cannot be deposited as a uniform film.

The step of patterning and separating the sub-hard mask is performed by plasma etching with a gas containing a fluorine-based gas including CF₄, C₂F₆, C₃F₈, C₄F₈, SF₆, NF₃, CHF₃ and HF or with a gas mainly composed of a rare gas including He, Ne, Ar, Kr and Xe.

<Wet Release Layer>

For the wet release layer in the method of this embodiment, a metal layer capable of being removed by a wet release process with water, an acid, an alkali, an organic solvent or the like is used. For example, the layer is preferably formed of Mg when the releasing solution is water, Mo, Al, Sc, Ti, V, Mn, Y, Zr, Nb, La, Ce, Nd, Sm, Eu, Gd or Hf for an acid, Al, Zn Sn, Pb, Ga or In for an alkali, and photocurable or thermosetting resins for an organic solvent.

<Patterning of Sub-Hard Mask>

In the case of using a sub-hard mask, after imprinting and removal of the resist residue, the hard mask is patterned based on the pattern of the imprinted resist. For the patterning of the sub-hard mask, RIE may be used or an ion beam etching method with He, Ne, Ar, Kr, Xe or the like may be employed. For example, when the main component of the sub-hard mask is Si, SiO₂, SixNy, SiON, Al, Ta or T, a gas mainly composed of a fluorine-based gas including CF₄, C₂F₆, C₃F₈, C₄F₈, SF₆, NF₃, CHF₃ and HF is suitably used.

In the case where the main component of the hard mask is Ag, Au, Co, Cr, Cu, Ni, Pd, Pt or Ru, ion beam etching with a fluorine-based gas such as CF₄ or a rare gas such as He, Ne, Ar, Kr and Xe is suitable. The patterning of the sub-hard mask is terminated at a stage when the surface of the hard mask is exposed.

<Patterning of Hard Mask>

In the case of using a sub-hard mask, the hard mask is patterned based on the pattern of the sub-hard mask. In the case of not using a sub-hard mask, after imprinting and removal of the resist residue, the hard mask is patterned based on the pattern of the imprinted resist. For the patterning of the hard mask, RIE may be used, or an ion beam etching method with He, Ne, Ar, Kr, Xe or the like may be employed.

For example, when the main component of the hard mask is C, a gas mainly composed of O₂ or O₃ is suitably used. In the case where the main component of the hard mask is Al, Si, Ta or Ti, ion beam etching with a fluorine-based gas such as CF₄ or a rare gas such as He, Ne, Ar, Kr and Xe is suitable. The patterning of the hard mask is terminated at a stage when the surface of the magnetic recording layer (in the case of using a wet release layer, the surface of the wet release layer) is exposed.

<Patterning of Wet Release Layer>

In the case of using a wet release layer, the wet release layer is patterned based on the pattern of the hard mask. For the patterning of the wet release layer, RIE with a fluorine-based gas including CF₄, C₂F₆, C₃F₈, C₄F₈, SF₆, NF₃, CHF₃ and HF, or RIE with a gas mainly composed of O₂ or O₃ may be used. An ion beam etching with He, Ne, Ar, Kr and Xe may also be employed.

<Removal of Mask Layer>

After the patterning of the magnetic recording layer, the mask layer is removed.

In the case of using a wet release layer, the mask with the overlying hard mask is separated by a wet process.

In the case of not using a wet release layer, the hard mask can be separated by plasma ashing with a gas mainly composed of O₂, O₃ or H₂ or a gas mainly composed of a fluorine-based gas or by ashing using RIE.

### Example 2

A DTR medium was manufactured by the method of Example 1. In order to vary the amount of C implanted, the CH₄ gas ion beam irradiation time is changed in the range from 0 seconds to 100 seconds as shown in Table 1. As Comparative Example, a medium subjected to magnetism deactivation by CF₄ irradiation but not by CH₄ irradiation was prepared.

The relationship between the CH₄ irradiation time and the medium characteristics is shown in Table 1.

The C content (%, atomic ratio to Co) in the non-recording area was measured by XPS, and the results are shown in Table 1. The medium was mounted on a drive and subjected to a fringe test. The error ratio was measured after performing adjacent recording 1,000 times under the conditions that the magnetic land width of the medium was 54 nm, the groove width was 16 nm, the effective recording head width (MWW) was 80 nm and the effective reproduction head width (MRW) was 50 nm.

In a medium where the CH₄ irradiation time is from 2.2 to 100 seconds, the error ratio was 10⁻⁵ or less and the medium was confirmed to operate as a DTR medium without problem. In a medium where the irradiation time was 1.3 seconds and the C content was 0.7%, magnetization remained in the non-recording area and the error ratio could not be measured. Similarly, in a medium not irradiated with CH₄, the error ratio could not also be measured. In the medium with a low C content, the fringe test is considered to result in NG due to insufficient deactivation of the magnetism.

Furthermore, an environmental test was performed. Each medium was placed under high-temperature high-humidity conditions at 80° C. and a humidity of 80% and the time until the error ratio could not be measured was examined, as a result, an environmental resistance of 400 hours or more was confirmed except for Comparative Example 1.

In the drive of Comparative Example 1, measurement of the error ratio became impossible in 24 hours. It is presumed that fluorine migrates out of the non-recording area and deteriorates the magnetism of the recording area.

TABLE 1

| | C | Ms of Non- | ER (x-th | Environmental |
|---|---|---|---|---|
| CH₄ Irradiation | Content | Recording | power | Resistance |
| Time [sec] | (%) | Area (%) | of 10) | [hour] |
| 100 | 75 | 0 | −6.7 | >400 |
| 60 | 50 | 0 | −6.5 | >400 |
| 36 | 31 | 10 | −5.5 | >400 |
| 24 | 20 | 20 | −5.3 | >400 |
| 15 | 15 | 60 | −5.1 | >400 |
| 2.2 | 1 | 87 | −5.0 | >400 |
| 1.3 | 0.7 | 95 | unmeasurable | — |
| 0 | 0 | 100 | unmeasurable | — |
| 0 (CF₃ deactivation, | 0 | 30 | −5.0 | 24 |
| Comparative | | | | |
| Example 1) | | | | |

These results reveal that the medium containing C in the non-recording area is good in fringe characteristics and environmental resistance and exhibits sufficient performance as a DTR medium.

### Example 3

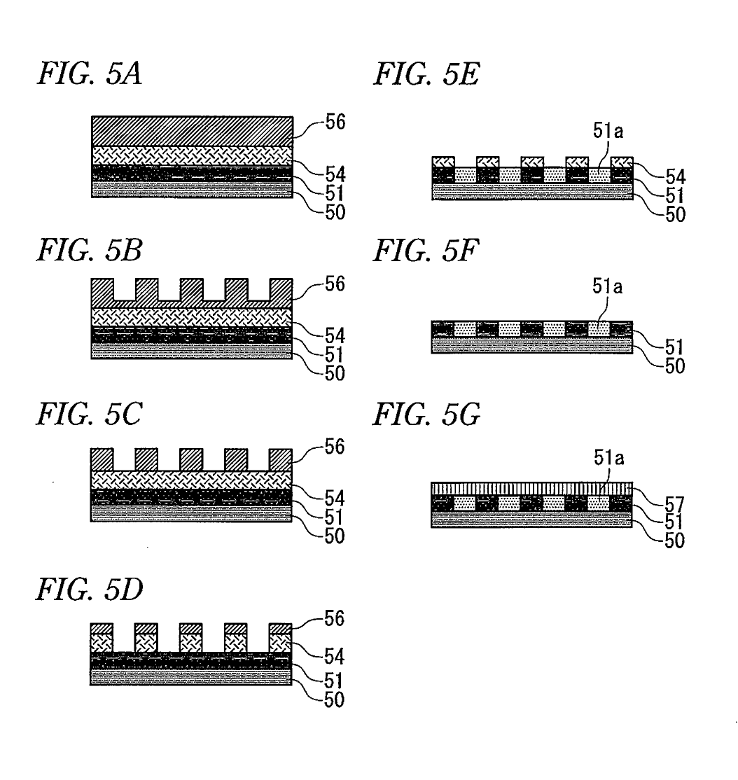

As shown in FIG. 5A, a 40 nm-thick soft magnetic layer (CoZrNb) (not shown), a 20 nm-tick orientation controlling underlying layer (Ru) (not shown), a 20 nm-thick magnetic recording layer 51 (CoCrPt—SiO₂) and a 30 nm-thick hard mask 54 composed of carbon are deposited on a glass substrate 50. On the hard mask 54, a resist 56 is spin-coated to have a thickness of 50 nm.

Separately, a stamper 60 having a concave/convex pattern (for example, as shown in FIG. 2 or 3) formed thereon is prepared. The stamper 60 is produced through EB lithography, Ni electroforming and injection molding. The stamper 60 is disposed by arranging its concave/convex surface to face the resist 56.

As shown in FIG. 5B, the stamper 60 is imprinted on the resist 56 to transfer the concave/convex pattern of the stamper 60 to the resist 56. Thereafter, the stamper 60 is removed. A resist residue is remaining in the bottom of the concave of the concave/convex pattern transferred to the resist 56. For the resist, SOG (spin-on-glass) mainly composed of siloxane is used.

As shown in FIG. 5C, the resist residue in the concave is removed by dry etching to expose the surface of the hard mask 54. This process is performed, for example, in an inductively coupled plasma (ICP) RIE apparatus by using CF₄ as the process gas and setting the chamber pressure to 0.1 Pa, the coil RF power and the platen RF power to 100 W and 50 W, respectively, and the etching time to 60 seconds.

As shown in FIG. 5D, the pattern is transferred by etching the hard mask 54 composed of carbon while using the resist 56 as the mask, to expose the surface of the magnetic recording layer 51 in concave parts.

This process is performed, for example, in an inductively coupled plasma (ICP) RIE apparatus by using O₂ as the process gas and setting the chamber pressure to 0.1 Pa, the coil RF power and the platen RF power to 100 W and 50 W, respectively, and the etching time to 30 seconds.

As shown in FIG. 5E, implantation of C element into the magnetic recording layer 51 is performed to form a C-containing layer 51a. This process is performed, for example, with an ECR (electron cyclotron resonance) ion gun by using a CH₄ gas at a gas pressure of 0.04 Pa with a microwave power of 1,000 W and an accelerating voltage of 5,000 V for a processing time of 60 seconds.

As shown in FIG. 5F, the remaining hard mask 54 is removed. This process is performed, for example, in an oxygen ashing apparatus by using O₂ as the process gas and setting the chamber pressure to 1 Pa, the plasma power to 100 W and the etching time to 10 seconds.

As shown in FIG. 5G, a protective film 57 is formed by CVD (chemical vapor deposition) and a lubricant is coated thereon, whereby a patterned medium according to an embodiment is obtained.

The manufactured magnetic recording medium is mounted on a drive, and the error ratio is measured and found to be 10^{-6.4}, and continuous driving over 100 hours is confirmed. The medium manufactured by the process in this Example has good performance as a magnetic recording medium.

### Example 4

Magnetic recording mediums were manufactured by the same method as in Example 1 except that CO, CO₂, C₂H₂, C₂H₄, C₂H₆, C₃H₆, C₃H₈, C₄H₆, C₄H₈, C₄H₁₀, HCN or CH₃F was used in place of CH₄ as the ion beam source. Also, as Comparative Example, a medium whose magnetism deactivation was performed by CF₄ irradiation was prepared.

The relationship between the ion beam irradiation time and the medium characteristics is shown in Table 2.

TABLE 2

| | Irradiation | C | Ms of Non- | ER (x-th | Environmental |
|---|---|---|---|---|---|
| | Time | Content | Recording | power | Resistance |
| Gas Species | [sec] | (%) | Area (%) | of 10) | [hour] |
| CO | 60 | 45 | 0 | −6.1 | >400 |
| CO₂ | 60 | 40 | 0 | −6.2 | >400 |
| C₂H₂ | 40 | 51 | 0 | −5.8 | >400 |
| C₂H₄ | 40 | 55 | 0 | −5.9 | >400 |
| C₂H₆ | 40 | 58 | 0 | −6.2 | >400 |
| C₃H₆ | 30 | 47 | 0 | −5.8 | >400 |
| C₃H₈ | 30 | 51 | 0 | −5.9 | >400 |
| C₄H₆ | 25 | 45 | 0 | −5.5 | >400 |
| C₄H₈ | 25 | 49 | 0 | −5.6 | >400 |
| C₄H₁₀ | 25 | 53 | 0 | −5.8 | >400 |
| HCN | 60 | 62 | 0 | −6.7 | >400 |
| CH₃F | 60 | 59 | 10 | −5.5 | 200 |
| CF₄ | 300 | 0 | 30 | −5.0 | 24 |
| (Comparative | | | | | |
| Example 1) | | | | | |

The C content (%, atomic ratio to Co) of the non-recording area was measured by XPS, and the results are shown in Table 2. The medium was mounted on a drive, and the same fringe test as in Example 2 was performed. In all mediums, the error ratio was confirmed to be 10⁻⁵ or less and it is revealed that the non-recording area was deactivated without problem.

Also, each medium was subjected to an environmental test. The medium was placed under high-temperature high-humidity conditions at 80° C. and a humidity of 80% and the time until the error ratio could not be measured was examined, as a result, an environmental resistance of 400 hours or more was confirmed except for Comparative Example 1 and CH₃F.

In the drive of Comparative Example 1, measurement of the error ratio became impossible in 24 hours. In the case of CH₃F, although not so bad as in Comparative Example 1, measurement of the error ratio became impossible in 200 hours. It is presumed that fluorine migrates out of the non-recording area and deteriorates the magnetism of the recording area.

These results reveal that when the gas of Examples above is used for the source, the medium is good in fringe characteristics and environmental resistance and exhibits sufficient performance as a DTR medium.

### Example 5

Magnetic recording mediums were manufactured by the same method as in Example 1 except that an assist gas He, Ne, Ar, Kr, Xe, H₂, N₂, O₂ or O₃ was mixed with CH₄ as the ion beam source. The assist gas was mixed in a ratio to give a partial pressure ratio of 50%.

Also, as Comparative Examples, a medium manufactured without using an assist gas and a medium whose magnetism deactivation was performed by CF₄ irradiation were prepared.

The relationship between the assist gas species and the medium characteristics is shown in Table 3.

The C content (%, atomic ratio to Co) of the non-recording area was measured by XPS, and the results are shown in Table 3. The medium was mounted on a drive, and the same fringe test as in Example 2 was performed. In all mediums, the error ratio was confirmed to be 10⁻⁵ or less and it is revealed that the non-recording area was deactivated without problem.

Also, in all mediums except for Comparative Examples, despite a short irradiation time compared with CH₄ alone, the error ratio is equal to or smaller than that when using CH₄ alone and this proves the assist gas effect.

Also, each medium was subjected to an environmental test. The medium was placed under high-temperature high-humidity conditions at 80° C. and a humidity of 80% and the time until the error ratio could not be measured was examined, as a result, an environmental resistance of 400 hours or more was confirmed except for Comparative Example 1. In the drive of Comparative Example 1, measurement of the error ratio became impossible in 24 hours. It is presumed that fluorine migrates out of the non-recording area and deteriorates the magnetism of the recording area.

TABLE 3

| | Irradiation | C | Ms of Non- | ER (x-th | Environmental |
|---|---|---|---|---|---|
| Assist Gas | Time | Content | Recording | power | Resistance |
| Species | [sec] | (%) | Area (%) | of 10) | [hour] |
| He | 50 | 60 | 0 | −6.7 | >400 |
| Ne | 50 | 58 | 0 | −6.6 | >400 |
| Ar | 50 | 61 | 0 | −6.9 | >400 |
| Kr | 40 | 63 | 0 | −6.8 | >400 |
| Xe | 40 | 65 | 0 | −6.6 | >400 |
| H₂ | 55 | 52 | 0 | −6.5 | >400 |
| N₂ | 30 | 51 | 0 | −6.9 | >400 |
| O₂ | 25 | 43 | 0 | −6.7 | >400 |
| None (CH₄) | 60 | 50 | 0 | −6.5 | >400 |
| None (CF₄) | 300 | 0 | 30 | −5.0 | 24 |
| (Comparative | | | | | |
| Example 1) | | | | | |

Not only CH₄ but also other C-containing gases were tested, but the results were the same. These results reveal that when the gas described in claim 10 is used, the medium is good in fringe characteristics and environmental resistance and exhibits sufficient performance as a DTR medium.

### Example 6

Magnetic recording mediums were manufactured by the same method as in Example 1 except that an assist gas He was mixed with CH₄ as the ion beam source to give a partial pressure ratio of 25%, 50%, 75% or 85%.

Also, as Comparative Examples, a medium manufactured without using an assist gas and a medium whose magnetism deactivation was performed by CF₄ irradiation were prepared.

The relationship between the assist gas species and the medium characteristics is shown in Table 4.

The C content (%, atomic ratio to Co) of the non-recording area was measured by XPS, and the results are shown in Table 4. The medium was mounted on a drive, and the same fringe test as in Example 2 was performed. In all mediums where the He partial pressure was 75% or less, the error ratio was confirmed to be 10⁻⁵ or less and it is revealed that the non-recording area was deactivated without problem.

Also, the assist gas effect was confirmed. In the medium where the He partial pressure of 85%, the C content is smaller than in other mediums with a lower He partial pressure, Ms in the non-recording area is liable to remain and in turn, the error ratio is slightly inferior to that in the case of CH₄ alone.

Furthermore, each medium was subjected to an environmental test. The medium was placed under high-temperature high-humidity conditions at 80° C. and a humidity of 80% and the time until the error ratio could not be measured was examined, as a result, an environmental resistance of 400 hours or more was confirmed except for Comparative Example 1. In the drive of Comparative Example 1, measurement of the error ratio became impossible in 24 hours. It is presumed that fluorine migrates out of the non-recording area and deteriorates the magnetism of the recording area.

TABLE 4

| | Irradiation | C | Ms of Non- | ER (x-th | Environmental |
|---|---|---|---|---|---|
| He Partial | Time | Content | Recording | power | Resistance |
| Pressure (%) | [sec] | (%) | Area (%) | of 10) | [hour] |
| 25 | 50 | 53 | 0 | −6.5 | >400 |
| 50 | 50 | 60 | 0 | −6.7 | >400 |
| 75 | 60 | 51 | 0 | −6.9 | >400 |
| 85 | 50 | 30 | 10 | −5.5 | >400 |
| None (CH₄) | 60 | 50 | 0 | −6.5 | >400 |
| None (CF₄) | 300 | 0 | 30 | −5.0 | 24 |
| (Comparative | | | | | |
| Example 1) | | | | | |

These results reveal that, when the gas of this embodiment is used as an assist gas with the concentration of 75% or less, the medium is good in fringe characteristics and environmental resistance and exhibits sufficient performance as a DTR medium.

### Example 7

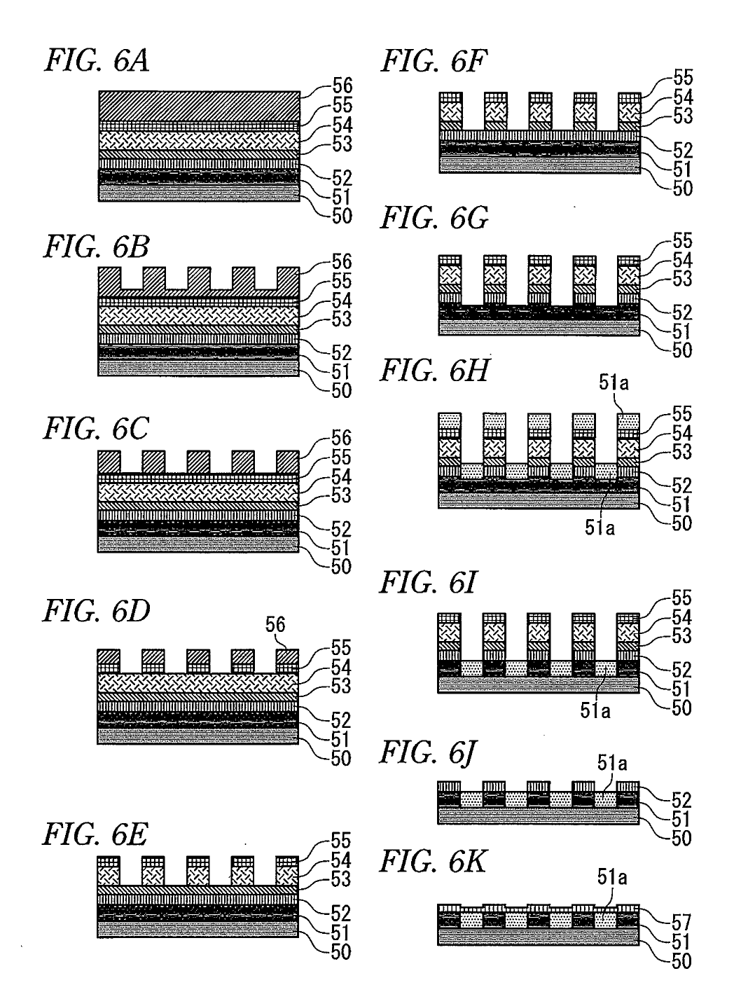

Another example of the method for manufacturing a magnetic recording medium according to this embodiment is described below by referring to FIGS. 6A to 6K.

As shown in FIG. 6A, a 40 nm-thick soft magnetic layer (CoZrNb) (not shown), a 20 nm-tick orientation controlling underlying layer (Ru) (not shown), a 20 nm-thick magnetic recording layer 51 (CoCrPt—SiO₂) and a 5 nm-thick DLC protective layer 52 are deposited on a glass substrate 50. A 5 nm-thick first hard mask 53 composed of Mo, a 25 nm-thick second hard mask 54 composed of carbon, and a 3 nm-thick third hard mask 55 composed of Si are deposited thereon.

On the third hard mask 55, a resist 56 is spin-coated to have a thickness of 50 nm. Separately, a stamper 60 having a concave/convex pattern (for example, as shown in FIG. 2 or 3) formed thereon is prepared. The stamper 60 is produced through EB lithography, Ni electroforming and injection molding. The stamper 60 is disposed by arranging its concave/convex surface to face the resist 56.

As shown in FIG. 6B, the stamper 60 is imprinted on the resist 56 to transfer the concave/convex pattern of the stamper 60 to the resist 56. Thereafter, the stamper 60 is removed. A resist residue is remaining in the bottom of the concave of the concave/convex pattern transferred to the resist 56.

As shown in FIG. 6C, the resist residue in the concave is removed by dry etching to expose the surface of the third hard mask 55. This process is performed, for example, in an inductively coupled plasma (ICP) RIE apparatus by using CF₄ as the process gas and setting the chamber pressure to 0.1 Pa, the coil RF power and the platen RF power to 100 W and 50 W, respectively, and the etching time to 60 seconds.

As shown in FIG. 6D, the pattern is transferred to the third hard mask 55 by ion beam etching while using the patterned resist 56 as the mask, to expose the second hard mask 54 in concave parts. This process is performed, for example, in an inductively coupled plasma (ICP) RIE apparatus by using CF₄ as the process gas and setting the chamber pressure to 0.1 Pa, the coil RF power and the platen RF power to 100 W and 50 W, respectively, and the etching time to 20 seconds.

As shown in FIG. 6E, the pattern is transferred by etching the second hard mask 54 composed of C while using the patterned third hard mask 55 as the mask, to expose the surface of the first hard mask 53 in concave parts.

This process is performed, for example, in an inductively coupled plasma (ICP) RIE apparatus by using O₂ as the process gas and setting the chamber pressure to 0.1 Pa, the coil RF power and platen RF power to 100 W and 50 W, respectively, and the etching time to 20 seconds.

As shown in FIG. 6F, the pattern is transferred by etching the first hard mask 53 composed of Mo while using the patterned second hard mask 54 as the mask, to expose the surface of DLC 52 in concave parts. This process is performed, for example, in an ion milling apparatus by using an Ar gas and setting the chamber pressure to 0.06 Pa, the accelerating voltage to 400 V, and the etching time to 10 seconds.

As shown in FIG. 6G, the pattern is transferred by etching DLC 52 while using the patterned first hard mask 53 as the mask, to expose the surface of the magnetic recording layer 51 in concave parts. This process is performed, for example, in an inductively coupled plasma (ICP) RIE apparatus by using O₂ as the process gas and setting the chamber pressure to 0.1 Pa, the coil RF power and the platen RF power to 100 W and 50 W, respectively, and the etching time to 5 seconds.

As shown in FIG. 6H, C as an implantation layer 51a is deposited on the magnetic recording layer 51 to a thickness of 10 nm. This process is performed, for example, by DC sputtering using an Ar gas by setting the plasma power to 500 W and the film-deposition time to 30 seconds.

As shown in FIG. 6I, implantation of C element into the magnetic recording layer 51 is performed. This process is performed, for example, with an ECR (electron cyclotron resonance) ion gun by using an He gas at a gas pressure of 0.1 Pa with a microwave power of 1,000 W and an accelerating voltage of 5,000 V for a processing time of 100 seconds.

As shown in FIG. 6J, the remaining first hard mask (Mo) 53 with the layer thereon is removed. In this process, for example, the medium is dipped in aqueous hydrogen peroxide and held for 1 minute to remove all of the remaining second hard mask 54 and the film deposited thereon.

As shown in FIG. 6K, a protective film 57 is formed by CVD (chemical vapor deposition) and a lubricant is coated thereon, whereby a patterned medium according to this embodiment is obtained.

A DTR medium was manufactured by the above-described method, and the C content (%, atomic ratio to Co) in the non-recording area of the medium obtained was measured by XPS and found to be 52%. The medium was mounted on a drive, and the same fringe test as in Example 2 was performed.

The error ratio was 10^{-6.0}. Furthermore, the same environmental test as in Example 2 was performed, and an environmental resistance of 400 hours or more was confirmed.

These results reveal that the DTR medium manufactured by this method has sufficient performance.

### Example 8

Magnetic recording mediums were manufactured by the same method as in Example 7 except that CN, AlC, SiC, TiC, VC, CrC, ZrC, NbC, MoC, TaC or WC was used in place of C as an implantation layer.

The relationship between the implantation layer and the medium characteristics is shown in Table 5.

The C content (%, atomic ratio to Co) in the non-recording area was measured by XPS, and the results are shown in Table 5. The medium was mounted on a drive and subjected to the same fringe test as in Example 2. In all mediums except for Comparative Example 1, the error ratio was confirmed to be 10⁻⁵ or less and it is revealed that the non-recording area was deactivated without problem.

Also, each medium was subjected to an environmental test. The medium was placed under high-temperature high-humidity conditions at 80° C. and a humidity of 80% and the time until the error ratio could not be measured was examined, as a result, an environmental resistance of 400 hours or more was confirmed except for Comparative Example 1. In the drive of Comparative Example 1, measurement of the error ratio became impossible in 24 hours. It is presumed that fluorine migrates out of the non-recording area and deteriorates the magnetism of the recording area.

TABLE 5

| | Irradiation | C | Ms of Non- | ER (x-th | Environmental |
|---|---|---|---|---|---|
| Implantation | Time | Content | Recording | power | Resistance |
| Layer | [sec] | (%) | Area (%) | of 10) | [hour] |
| CN | 100 | 51 | 0 | −6.3 | >400 |
| AlC | 100 | 52 | 0 | −6.2 | >400 |
| SiC | 100 | 49 | 0 | −5.8 | >400 |
| TiC | 100 | 48 | 0 | −6.1 | >400 |
| VC | 100 | 45 | 0 | −6.5 | >400 |
| CrC | 100 | 46 | 0 | −6.8 | >400 |
| ZrC | 100 | 50 | 0 | −6.3 | >400 |
| NbC | 100 | 51 | 0 | −5.8 | >400 |
| MoC | 100 | 46 | 0 | −5.9 | >400 |
| TaC | 100 | 51 | 0 | −6.0 | >400 |
| WC | 100 | 50 | 0 | −6.4 | >400 |
| C | 100 | 52 | 0 | −6.0 | >400 |
| None (CF₄) | 300 | 0 | 30 | −5.0 | 24 |
| (Comparative | | | | | |
| Example 1) | | | | | |

These results reveal that when the material described in claim 12 is used for the implantation layer, the medium is good in fringe characteristics and environmental resistance and exhibits sufficient performance as a DTR medium.

### Example 9

Magnetic recording mediums were manufactured by the same method as in Example 6 except that Ne, Ar, Kr or Xe was used in place of He as the ion beam source for implantation.

The relationship between the beam source and the medium characteristics is shown in Table 6.

The C content (%, atomic ratio to Co) of the non-recording area was measured by XPS, and the results are shown in Table 6. The medium was mounted on a drive, and the same fringe test as in Example 2 was performed. In all mediums except for Comparative Example 1, the error ratio was confirmed to be 10⁻⁵ or less and it is revealed that the non-recording area was deactivated without problem.

Furthermore, each medium was subjected to an environmental test. The medium was placed under high-temperature high-humidity conditions at 80° C. and a humidity of 80% and the time until the error ratio could not be measured was examined, as a result, an environmental resistance of 400 hours or more was confirmed except for Comparative Example 1. In the drive of Comparative Example 1, measurement of the error ratio became impossible in 24 hours. It is presumed that fluorine migrates out of the non-recording area and deteriorates the magnetism of the recording area.

TABLE 6

| | Irradiation | C | Ms of Non- | ER (x-th | Environmental |
|---|---|---|---|---|---|
| | Time | Content | Recording | power | Resistance |
| Gas Species | [sec] | (%) | Area (%) | of 10) | [hour] |
| Ne | 100 | 54 | 0 | −6.3 | >400 |
| Ar | 100 | 59 | 0 | −6.2 | >400 |
| Kr | 100 | 63 | 0 | −6.5 | >400 |
| Xe | 100 | 69 | 0 | −6.6 | >400 |
| He | 100 | 52 | 0 | −6.0 | >400 |
| None (CF₄) | 300 | 0 | 30 | −5.0 | 24 |
| (Comparative | | | | | |
| Example 1) | | | | | |

The test was performed for other implantation layers, but the results were the same. These results reveal that when the above material is used for the implantation layer, the medium is good in fringe characteristics and environmental resistance and exhibits sufficient performance as a DTR medium.

According to the above-described embodiment, a method capable of manufacturing a magnetic recording medium in which the environmental resistance of the non-recording area is increased while surely deactivating the non-recording area, the flying property of the recording/reproducing head is ensured with good head-positioning precision, the SN ratio is good, and high reliability is exhibited even in a high-temperature high-humidity environment, can be provided.

1. A method for manufacturing a magnetic recording medium, the method comprising:
depositing a magnetic recording layer on a substrate;
forming a mask on a region of the magnetic recording layer corresponding to a recording area;
irradiating another region of the magnetic recording layer where the mask is not formed with an ion beam using a C-containing gas as a source gas to deactivate the another region and to thereby form a non-recording area; and
forming a protective film over an entire surface of the substrate.

2. The method of claim 1,
wherein the non-recording area is formed to be higher in a C concentration than the recording area.

3. The method of claim 1,
wherein the non-recording area has a C concentration of 1% or more of a magnetic element.

4. The method of claim 1,
wherein the mask is mainly composed of carbon.

5. The method of claim 1,
wherein the source gas of the ion beam includes at least one selected from a group consisting of CO, CO₂, CH₄, C₂H₂, C₂H₄, C₂H₆, C₃H₆, C₃H₈, C₄H₆, C₄H₈, C₄H₁₀, HCN, CH₃F and a mixture thereof.

6. The method of claim 5,
wherein the source gas of the ion beam further includes at least one selected from a group consisting of He, Ne, Ar, Kr, Xe, H₂, N₂, O₂, O₃ and a mixture thereof.

7. The method of claim 1, further comprising:
after forming the mask, depositing a C-containing layer on the mask to cause a C element to be diffused into the recording layer by an ion beam irradiation.

8. The method of claim 7,
wherein the C-containing layer has a C concentration of 50% or more.

9. The method of claim 8,
wherein the C-containing layer includes at least one selected from a group consisting of C, CN, AlC, SiC, TiC, VC, CrC, ZrC, NbC, MoC, TaC, WC and a mixture thereof.

10. The method of claim 7,
wherein the source gas of the ion beam further includes at least one selected from a group consisting of He, Ne, Ar, Kr, Xe and a mixture thereof.

11. The method of claim 1,
wherein the non-recording area contains at least a constituent element of the recording area.
